(19) United States
(12) Patent Application Publication
(10) Pub. No.: US 2011/0091821 A1
(43) Pub. Date: Apr. 21, 2011

(54) RESIST TREATMENT UNIT, RESIST COATING AND DEVELOPING APPARATUS, AND RESIST TREATMENT METHOD

(76) Inventor: Shinji Kobayashi, Yamanashi (JP)

(21) Appl. No.: 13/000,234

(22) PCT Filed: Jun. 10, 2009
(86) PCT No.: PCT/JP2009/060633

§ 371 Date: Dec. 20, 2010

(30) Foreign Application Priority Data
Jul. 7, 2008 (JP) 2008-177376

(51) Int. Cl. G03F 7/26; B05C 9/12; G03B 27/52

(52) U.S. Cl. 430/327; 118/50.1; 355/27

(57) ABSTRACT

A resist treatment unit for performing treatment on a resist film which has been formed on a substrate is disclosed. This resist treatment unit includes: a treatment container capable of maintaining a vacuum therein; a mounting table provided in the treatment container for mounting the substrate on which the resist film has been formed thereon; a gas supply part for jetting a mixture gas containing a first gas and a second gas which are chemically inert toward the mounting table at a predetermined flow rate; and an exhaust part capable of exhausting the treatment container to a degree of vacuum at which the mixture gas jetted from the gas supply part at the predetermined flow rate is able to be a molecular beam in the treatment container.

### TECHNICAL FIELD

The present invention relates to a resist treatment unit for treating a resist film which has been formed on a substrate, a resist coating and developing apparatus, and a resist treatment method.

### BACKGROUND ART

Recently, to realize further miniaturization of a circuit pattern, extreme ultraviolet ray (EUV) lithography using extreme ultraviolet ray is under consideration. In the EUV lithography, the extreme ultraviolet ray is applied to, for example, a chemically amplified resist film in vacuum, whereby the resist film is exposed.

Since the application of the extreme ultraviolet ray is performed in an exposure chamber maintained under vacuum in the EUV lithography as described above, the resist film is likely to produce an outgas and the outgas sometimes contaminates a photomask and reflective optics. If such contamination occurs, the exposure light is scattered or the intensity of the exposure light decreases, and therefore it is sometimes impossible to expose the resist film into a predetermined pattern. Especially, to reduce LER (Line Edge Roughness) that has been acknowledged as a problem in the 90 nm generation and thereafter, it is first important to eliminate the exposure error due to the contamination of the exposure apparatus.

In order to reduce the outgas, proposed is a method of reducing the outgas in the exposure apparatus by evaporating a residual solvent in the resist film by application of electronic ray, ultraviolet ray, or far ultraviolet ray to the resist film after the resist film is pre-baked (Patent Document 1).

### PRIOR ART DOCUMENT

### Patent Document

Patent Document 1: Japanese Patent No. 3816006

### DISCLOSURE OF THE INVENTION

### Problems to be Solved by the Invention

However, to apply those energy rays, a large-size apparatus may be required. Therefore, the resist coating and developing apparatus and the exposure apparatus becomes expensive, and the footprint increases, resulting in an increase in manufacturing cost of the semiconductor device. Further, such energy rays may deteriorate the characteristics of the resist. Furthermore, the possibility of adversely affecting the structure created in the semiconductor wafer before the photolithography process cannot be denied.

The present invention has been made in consideration of the above situation and provides a resist treatment unit, a resist coating and developing apparatus, and a resist treatment method each capable of realizing an appropriate patterning of a resist film by reducing the amount of an outgas produced from the resist film in an exposure process.

### Means for Solving the Problems

To achieve the above object, a first aspect of the present invention provides a resist treatment unit for performing treatment on a resist film which has been formed on a substrate, the unit including: a treatment container capable of maintaining a vacuum therein; a mounting table provided in the treatment container for mounting the substrate on which the resist film has been formed thereon; a gas supply part for jetting a mixture gas containing a first gas and a second gas which are chemically inert toward the mounting table at a predetermined flow rate; and an exhaust part capable of exhausting the treatment container to a degree of vacuum at which the mixture gas jetted from the gas supply part at the predetermined flow rate is able to be a molecular beam in the treatment container.

A second aspect of the present invention provides a resist coating and developing apparatus, including: a resist coating unit for applying a resist film onto a substrate; a resist treatment unit for performing a predetermined treatment on the resist film, the resist treatment unit being the resist treatment unit as set forth in any one of claims 1 to 5; and a developing unit for developing the resist film for which the predetermined treatment has been performed and exposure processing has been performed.

A third aspect of the present invention provides a resist treatment method, including the steps of: mounting a substrate on which a resist film has been formed on a mounting table provided in a treatment container; exhausting the treatment container to be able to form a molecular beam in the treatment container; and jetting a mixture gas containing a first gas and a second gas which are chemically inert into the treatment container to form a molecular beam, and applying the molecular beam to the substrate mounted on the mounting table.

### BRIEF DESCRIPTION OF THE DRAWINGS

FIG. 1 A schematic sectional view showing a resist treatment unit according to an embodiment of the present invention.

FIG. 2 A view explaining scanning of a wafer in the resist treatment unit in FIG. 1, showing the positional relation between the wafer mounted on a mounting table in the resist treatment unit and a gas nozzle.

FIG. 3 A view explaining scanning of a wafer in the resist treatment unit in FIG. 1, showing the positional relation between the wafer mounted on the mounting table in the resist treatment unit and the gas nozzle.

FIG. 4 A graph showing the dependence of the temperature of a Xe molecule in a mixture gas of He and Xe on the Xe concentration.

FIG. 5 A schematic top view showing a coating and developing apparatus according to an embodiment of the present invention.

FIG. 6 A schematic side view showing the coating and developing apparatus according to the embodiment of the present invention.

FIG. 7 Another schematic side view showing the coating and developing apparatus according to the embodiment of the present invention.

FIG. 8 A view showing an example of the gas nozzle in the resist treatment unit in FIG. 1 and in the coating and developing apparatus in FIG. 5.

FIG. 9 A view explaining scanning of a wafer in a resist treatment unit according to another embodiment of the present invention, showing the positional relation between the wafer mounted on a mounting table in the resist treatment unit and a gas nozzle.

FIG. 10A A top view schematically showing a resist treatment unit according to another embodiment of the present invention.

FIG. 10B A side view of the resist treatment unit shown in FIG. 10A.

### BEST MODE FOR CARRYING OUT THE INVENTION

According to an embodiment of the present invention, a resist treatment unit, a resist coating and developing apparatus and a resist treatment method are provided each capable of realizing an appropriate patterning of a resist film by reducing the amount of outgas produced from the resist film in an exposure process. Hereinafter, an unlimited illustrative embodiment of the present invention will be described with reference to the accompanying drawings. In all of the accompanying drawings, the same or corresponding members or components will be referred to with the same or corresponding reference numerals or letters, while omitting their overlapping descriptions. Further, the drawings are not intended to show the relative ratio among the members or components, and therefore concrete dimensions should be determined by the person skilled in the art in light of the following unlimited embodiment.

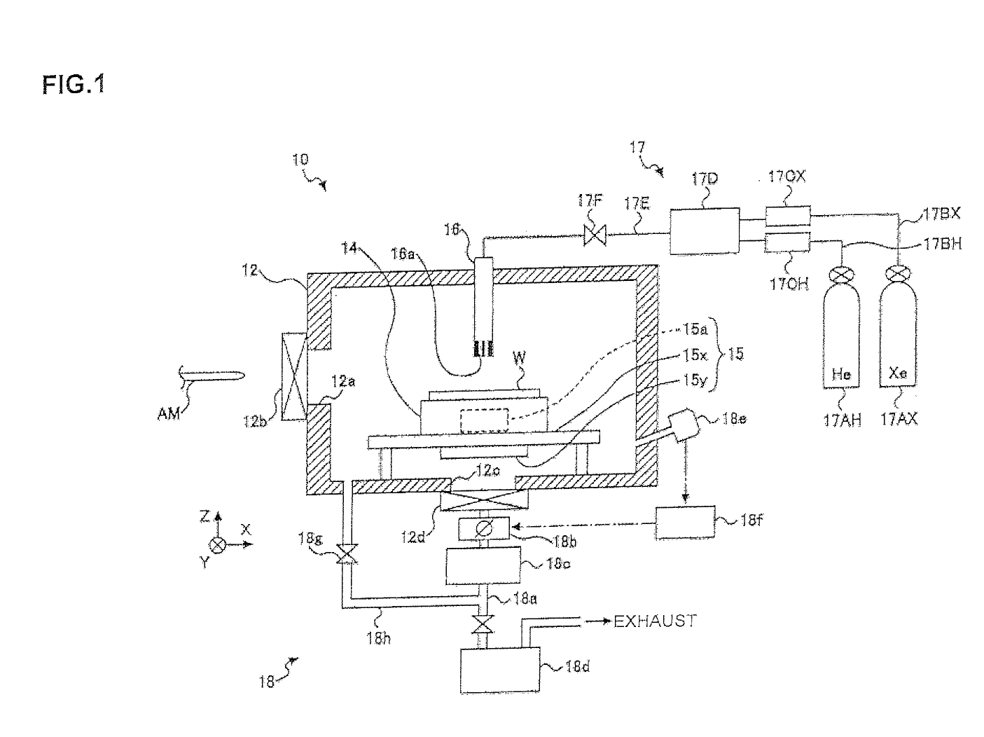

FIG. 1 is a schematic sectional view showing a resist treatment unit according to one embodiment of the present invention. This resist treatment unit (hereinafter, treatment unit) 10 is provided preferably in a resist coating and developing apparatus as will be described later. A wafer on which a resist film has been applied is carried into the treatment unit 10 in which a later-described treatment is performed on the wafer before the wafer is carried to an exposure apparatus.

Referring to FIG. 1, the treatment unit 10 includes a chamber 12 capable of maintaining a vacuum therein, a mounting table 14 which is arranged in the chamber 12 and on which the wafer W having the resist film form thereon is mounted, a gas nozzle 16 for jetting gas toward the wafer W mounted on the mounting table 14, and a vacuum system 18 exhausting the chamber 12 to a predetermined degree of vacuum.

To carry the wafer W into/out of the chamber 12, a side wall of the chamber 12 is provided with a carrier port 12a through which the wafer W is carried into the chamber 12 and carried out of the chamber 12. The carrier port 12a is opened/closed by a gate valve 12b attached to the side wall of the chamber 12. Further, the wafer W is carried into/out of the chamber 12 by a carrier arm AM.

At a bottom portion of the chamber 12, an exhaust port 12c is provided, and the vacuum system 18 is connected to the exhaust port 12c via a valve 12d. The valve 12d can open/close to shut the chamber 12 off from the vacuum system 18 or make them communicate with each other.

The vacuum system 18 includes a pressure regulating valve 18b provided in an exhaust pipe 18a connected to the valve 12d for regulating the degree of vacuum in the chamber 12, a high vacuum pump 18c such as a turbo-molecular pump provided in the exhaust pipe 18a downstream the pressure regulating valve 18b and capable of exhausting the chamber 12 to a high degree of vacuum, a dry pump 18d serving as an auxiliary pump of the high vacuum pump 18c, a pressure sensor 18e airtightly inserted in a through hole provided in the side wall of the chamber 12 for measuring the degree of vacuum in the chamber 12, and a pressure regulator 18f for controlling the pressure regulating valve 18b based on the degree of vacuum measured by the pressure sensor 18e to maintain the inside of the chamber 12 at a predetermined degree of vacuum. Further, the dry pump 18d is connected to the chamber 12 by a branch pipe 18h in which a valve 18g is provided, and serves also as a roughing pump.

The gas nozzle 16 is inserted, as shown in FIG. 1, into the chamber 12 through a through hole provided at a ceiling portion of the chamber 12 and attached to the ceiling portion in a manner to maintain the airtightness in the chamber 12. Though depending on the size of the chamber 12, the inner diameter of the gas nozzle 16 can be, for example, about 1 mm to about 10 mm, and the length of the gas nozzle 16 can be, for example, about 30 mm to about 200 mm. Further, at a lower end of the gas nozzle 16, a plurality of orifices 16a are formed each having, but not limited to, for example, a diameter ranging from about 50 μm to about 100 μm.

The distance between the lower end of the gas nozzle 16 and the wafer W mounted on the mounting table 14 can be determined in consideration of the degree of vacuum in the chamber 12 and set to, for example, not longer than a mean free path of gas molecules under the predetermined degree of vacuum. Thus, the gas jetted from the orifices 16a of the gas nozzle 16 is applied as molecular beams to the wafer W mounted on the mounting table 14. The molecular beams are flow of gas molecules whose spatial distribution in the form of a line shape (or a band shape) travels in substantially straight lines in the chamber 12. For example, when the distance between the tip (the gas jetting end) of the gas nozzle 16 and the wafer W on the mounting table 14 is shorter than or substantially equal to the mean free path under the predetermined degree of vacuum, the flow of gas from the gas nozzle 16 to the wafer W can be considered to be molecular beams. Specifically, it is considered that given that nitrogen gas molecules have a mean free path of about 6 cm under a degree of vacuum of about 0.1 Pa (about 7.5×10⁻⁴ Torr), the molecular beams will be formed when the pressure in the chamber 12 is at a degree of vacuum ranging from about 0.5 Pa to about 1×10⁻⁵ Pa, though depending on the size of the chamber 12.

Referring to FIG. 1, an upper end of the gas nozzle 16 is connected to a gas supply system 17. The gas supply system 17 includes, but not limited to, a helium (He) gas cylinder 17AH, a mass flow controller (MFC) 17CH provided in a pipe 17BH connected to the gas cylinder 17AH for controlling the flow of He gas from the gas cylinder 17AH, a xenon (Xe) gas cylinder 17AX, a mass flow controller (MFC) 17CX provided in a pipe 17BX connected to the gas cylinder 17AX for controlling the flow of Xe gas from the gas cylinder 17AX, a buffer tank 17D for temporarily storing the He gas and the Xe gas and mixing them, and a valve 17F provided in a pipe 17E joining the buffer tank 17D and the gas nozzle 16.

The mounting table 14 provides, on its upper surface, a wafer mounting part on which the wafer W is to be mounted. The wafer mounting part may have, for example, an electrostatic chuck. Further, on the wafer mounting part, a plurality of positioning pins are arranged which may be used to position the wafer W to be mounted on the upper surface of the mounting table 14. Further, the mounting table 14 can have raising and lowering pins (not shown) for lowering the wafer W carried into the chamber 12 by the carrier arm AM onto the wafer mounting part (the upper surface of the mounting table 14). Further, the mounting table 14 may have a heater therein, which may be used to heat the wafer W. Furthermore, the mounting table 14 may have a flow path allowing a coolant to flow therethrough so that a temperature-controlled medium flowing through the flow path cools the wafer W. Further, a temperature controller keeping the temperature of the mounting table 14 at a predetermined temperature may be provided in the mounting table 14.

The mounting table 14 is supported by a mounting table supporting part 15 provided at the bottom of the chamber 12. The mounting table supporting part 15 includes a servomotor capable of controlling the rotation angle of the mounting table 14 or the like, and has a driving part 15a arranged inside the mounting table 14, an X-direction rail 15x supporting the mounting table 14 to be movable in an X-direction, and a Y-direction rail 15y supporting the mounting table 14 to be movable in a Y-direction orthogonal to the X-direction. Further, the mounting table supporting part 15 has a driving mechanism (not shown) such as, for example, a linear motor, which allows the mounting table 14 to move in the X-direction on the X-direction rail 15x and move in the Y-direction on the Y-direction rail 15y.

Next, the resist treatment in the treatment unit 10 of this embodiment will be described. First, a resist film is applied on the wafer W by a predetermined resist coating unit, and prebaking is performed on the resist film. This resist film may be prepared, for example, not for a specific photolithography process in the manufacturing process of a semiconductor device but for any photolithography process. When exposure is performed using EUV light for forming an etching mask having a fine pattern, the resist film may be preferably formed of a chemically amplified-type resist.

Next, the gate valve 12b is opened, and the prebaked wafer W is carried by the carrier arm AM into the chamber 12 through the carrier port 12a. The wafer W is received by the not-shown raising and lowering pins, and the raising and lowering pins are driven by a raising and lowering mechanism (not shown) to mount the wafer W on the mounting table 14 after the carrier arm AM is retracted from the chamber 12. Subsequently, the wafer W is held on the mounting table 14 by the electrostatic chuck (not shown). Further, the mounting table 14 is moved to a predetermined position (hereinafter, an initial position) by the driving part 15a and the driving mechanism (not shown).

Thereafter, the chamber 12 is roughly evacuated through the branch pipe 18h by the dry pump 18d. After the pressure inside the chamber 12 reaches a predetermined reduced pressure, the valve 12d is opened and the chamber 12 is exhausted to a high vacuum by the high vacuum pump 18c. After the pressure sensor 18e confirms that the degree of vacuum in the chamber 12 reached a low degree of vacuum at which the molecular beams can be formed in the chamber 12, the mixture gas of He and Xe supplied from the gas supply system 17 is jetted to the wafer W mounted on the mounting table 14 through the orifices 16a of the gas nozzle 16. The mixture gas jetted from the orifices 16a becomes molecular beams and applied to a predetermined area (hereinafter, referred to as an application area) of the resist film on the wafer W. Further, the inside of the chamber 12 is maintained at a predetermined degree of vacuum by the pressure sensor 18e, the pressure regulator 18f, and the pressure regulating valve 18b.

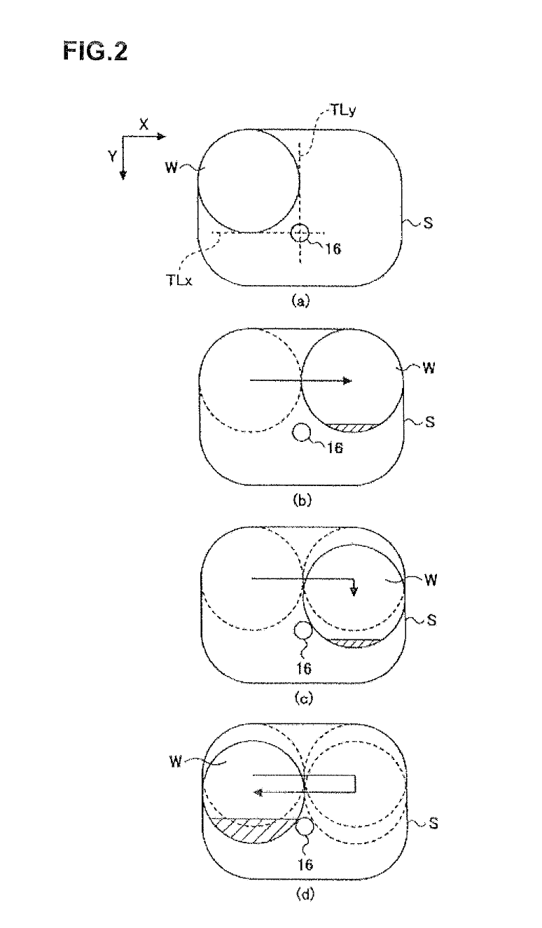

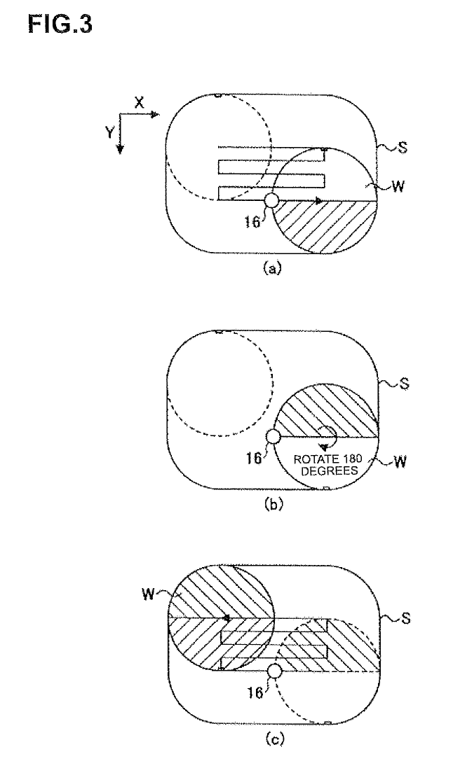

Subsequently, the mounting table 14 is moved by the driving part 15a and the driving mechanism (not shown) to thereby scan the wafer W, and the molecular beams jetted from the orifices 16a of the gas nozzle 16 are applied to the entire surface of the resist film on the wafer W. One example of movement of the mounting table 14 will be described below referring to FIG. 2(a) to (d) and FIG. 3(a) to (c).

FIG. 2(a) to (d) and FIG. 3(a) to (c) are top views showing the positional relation of the wafer W mounted on the mounting table 14 with respect to the gas nozzle 16.

FIG. 2(a) shows the wafer W located at the initial portion. The wafer

W at the initial position is placed as shown in the drawing such that the gas nozzle 16 is located at an intersection of an X-direction tangent TLx and a Y-direction tangent TLy. Then, as shown in FIG. 2(b), the wafer W is scanned in a positive X-direction by the movement of the mounting table 14 (FIG. 1). Thus, the molecular beams of the mixture gas of He and Xe are applied from the gas nozzle 16 to a portion indicated by oblique lines in FIG. 2(b). Then, as shown in FIG. 2(c), the wafer W is moved by a predetermined distance in a positive Y-direction by the movement of the mounting table 14 (FIG. 1). This distance may be set to substantially equal to or slightly shorter than the width of the above-described application area in order not to leave a portion of the wafer W where the molecular beams of the mixture gas are not applied. Subsequently, the wafer W is scanned in a negative X-direction. Thus, as shown by oblique lines in FIG. 2(d), a portion of the wafer W where the molecular beams have been applied is enlarged.

Thereafter, as shown in FIG. 3(a), the above-described operation is repeated until the molecular beams are applied to a half of the wafer W. Then, the wafer W is rotated clockwise 180°, whereby the applied portion and an unapplied portion are changed (FIG. 3(b)). Thereafter, the mounting table 14 is moved reversely following the above-described path so that the molecular beams are applied to the unapplied portion (FIG. 3(c)).

As described above, the mixture gas of He and Xe jetted from the gas nozzle is applied to the entire surface of the resist film on the wafer W, whereby the resist film which has been formed on the wafer W is treated. Thus, the outgas in the subsequent exposure process is reduced. The principle of reduction of the outgas will be described below.

The mixture gas of He and Xe flowed from the gas supply system 17 into the gas nozzle 16 flows in a state like a viscous flow in the gas nozzle 16. Therefore, the He molecules and the Xe molecules (monatomic molecules) will flow in the same direction and at the same speed in the gas nozzle 16 while colliding with each other. Thereafter, when the mixture gas is jetted from the orifices 16a of the gas nozzle 16 (FIG. 1) into the treatment container 12, the molecular beams of the mixture gas are formed and both the He molecules and the Xe molecules will move in almost the same direction and at the same speed irrespective of their molecular weights. In this event, the intermolecular force hardly acts between the gas molecules. Under such status, the temperature of the gas molecule is determined by the molecular weight of the gas molecule and the specific heat at constant pressure. As described above, in the molecular beam of the mixture gas of He and Xe, the He molecule lighter than the mean molecular weight has a lower temperature, whereas the Xe molecule heavier than the mean molecular weight has a higher temperature. In other word, the Xe molecule in the molecular beam has a higher kinetic energy than the He molecule even when the Xe molecule moves at the same speed as the Xe molecule and there is no interaction between molecules, so that no or little energy is transmitted from the Xe molecule to the surrounding He molecule.

When such molecular beam is applied to the resist film, a relatively large energy of the Xe molecule transfers to a portion that the Xe molecule collides with to increase the temperature of the resist molecule at that portion and promote the molecular motion. This makes the resist molecule shift to a more stable state, with the result that the free volume (the space between polymer chains) reduces at that portion to densify the resist. In addition, because the energy of the Xe molecule is absorbed at a surface layer portion of the resist film at that portion, the densification will occur at the surface layer portion of the resist film at that portion. Accordingly, when the molecular beams of the mixture gas of He and Xe are applied to the resist film while the wafer W is being moved, a high density layer will be formed to cover almost the entire surface of the resist film, and the high density layer serves as a cap layer to block the outgas from the resist film. Therefore, the outgas from the resist film in the vacuum chamber of the exposure apparatus is reduced.

There are depressions and projections on the surface of the resist film after prebaking, and when the molecular beams are applied to the projecting portions and the energy of the Xe molecules transfers to the projecting portions, the resist molecules at the projecting portions have a lower constraint force from the surrounding resist molecules, as compared to the resist molecules at flat portions and therefore can relatively easily move by the energy from the Xe molecules. Accordingly, when the resist molecules move and are caught in the depressed portions on the surface of the resist film, the surface of the resist film is planarized. By planarizing the surface of the resist film, the scattering of incident exposure light is prevented and LER can be reduced.

Note that the energy (temperature) of the Xe molecule can be appropriately adjusted by the concentration of the Xe gas in the mixture gas, and accordingly the effect of reducing the outgas can also be adjusted by the concentration of the Xe gas. Hereinafter, how the temperature of the Xe molecule changes by the concentration of the Xe gas in the mixture gas will be described.

Since the He molecule and the Xe molecule are monatomic molecules and their vibrational and rotational energies are negligible, the energies of such molecules are, in consideration of the kinetic energies in the three directions of x, y, z,

(1/2)mv²=(3/2)kT (1)

where

m: molecular weight

v: molecular speed

k: Boltzmann constant

T: temperature of molecule. Here, assuming that the molecular weight of the Xe molecule is m_{Xe}, and the temperature of the Xe molecule is T_{Xe}, the energy of the Xe molecule can be expressed by

(1/2)m_{Xe}V²=(3/2)kT_{Xe} (2)

Further, assuming that the mean molecular weight of the mixture gas is mₐᵥₑ and the mean temperature is Tₐᵥₑ, the energy of the molecule of the mixture gas can be expressed by

(1/2)mₐᵥₑV²=(3/2)kTₐᵥₑ (3)

From Expression (2) and Expression (3), the relational expression

TXe=(m_{Xe}/mₐᵥₑ)×Tₐᵥₑ (4)

is obtained.

Meanwhile, assuming that the mol concentration of He in the mixture gas is C_{He} % and the mol concentration of Xe is C_{Xe} %, and because the molecular weight m_{He} of He is 4 and the molecular weight m_{Xe} of Xe is 132, the mean molecular weight mₐᵥₑ of the mixture gas can be expressed by

mₐᵥₑ=(C_{He}×4+C_{Xe}×132)/100 (5)

Accordingly, the temperature T_{Xe} of the Xe molecule is as follows.

T_{Xe}=m_{Xe}/((C_{He}×4+C_{Xe}×132)/100)×Tₐᵥₑ (6)

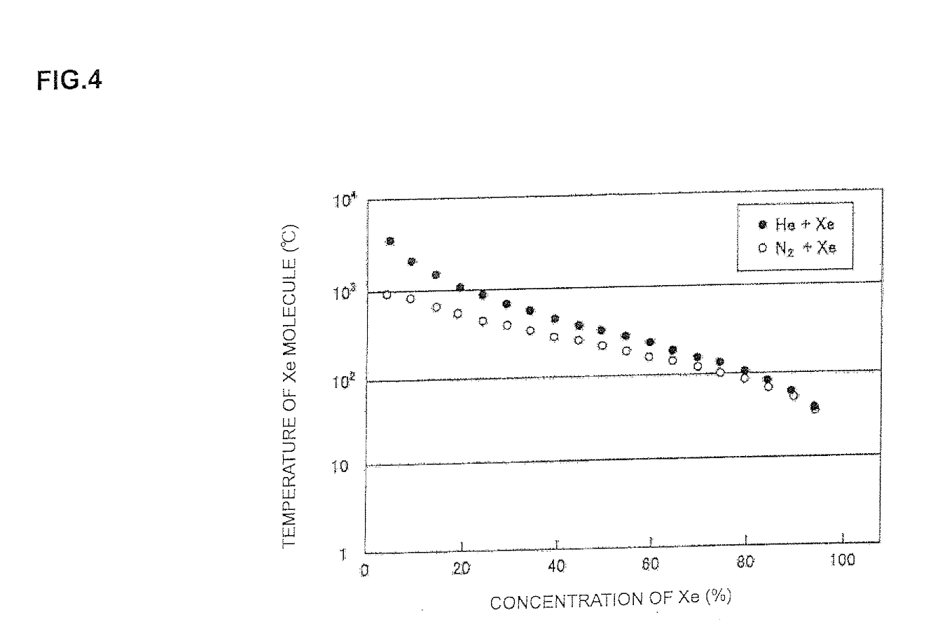

The relation of Expression (6) when the mean temperature Tₐᵥₑ of the mixture gas (the temperature in the chamber 12) is set to 23° C. is shown in FIG. 4. As shown in the drawing, by changing the Xe concentration in the mixture gas of He and Xe, the temperature of the Xe molecule can be changed in a wide range. For example, when the Xe concentration in the mixture gas of He and Xe is 5%, the Xe molecule can have a temperature about 12.7 times as high as the temperature in the chamber 12. Note that FIG. 4 also shows how the temperature of the Xe molecule in the mixture gas of nitrogen (N₂) gas and Xe gas changes according to the concentration of the Xe gas. It is found that the temperature of the Xe molecule can be increased even in such a mixture gas.

As described above, according to the resist treatment unit and treatment method according to this embodiment, the temperature of the surface layer portion of the resist film can be increased without heating the mixture gas of He and Xe, with the result that the surface layer portion of the resist film is densified. Therefore, even when the wafer W on which the resist film has been formed is exposed to light in vacuum, the outgas from the resist film is reduced to reduce the contamination in the exposure apparatus.

Further, in the resist treatment unit and treatment method according to this embodiment, since only the molecular beams need to be applied, damage to the wafer is reduced, and since only the surface layer portion of the resist film is heated, there is no or little effect of the temperature on the resist film. Further, since increasing the purities of the He gas and the Xe gas is relatively easy, the wafer is secure from contamination by the molecular beams. Further, the resist treatment unit and treatment method according to this embodiment have an advantages that they do not require a large-size apparatus as compared to application of electronic ray, ultraviolet ray, or far ultraviolet ray to the resist film.

Further, reduction of the contamination in the exposure apparatus can reduce the frequency of maintenance of the exposure apparatus and contribute to improvement in throughput.

Note that according to the above-described movement example of the wafer W, since the wafer W is rotated 180°, the moving range of the wafer W can be narrowed. As is clear from FIG. 2 and FIG. 3, a space S required for movement of the wafer W needs to have a length about twice the diameter of the wafer W in the X-direction but only needs to have a length about 1.5 times the diameter of the wafer W in the Y-direction. Accordingly, the footprint of the resist treatment unit 10 can be reduced.

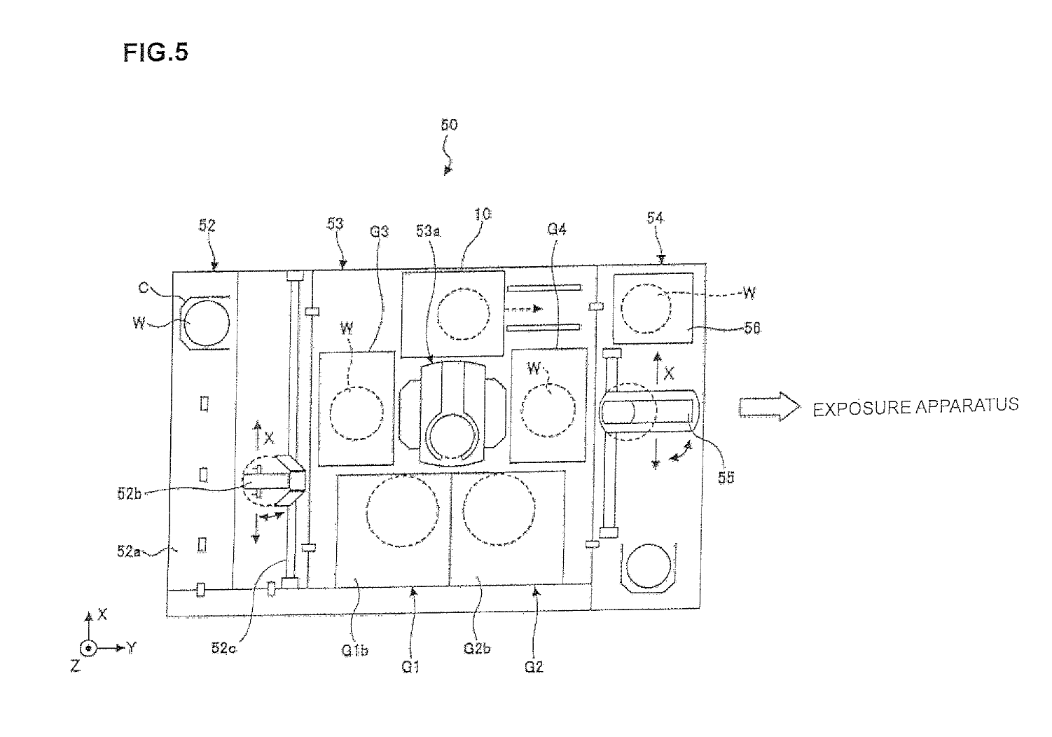

Next, a coating and developing apparatus according to an embodiment of the present invention in which the above-described resist treatment unit 10 is installed will be described with reference to FIG. 5 to FIG. 7. As shown in FIG. 5, a coating and developing apparatus 50 has a cassette station 52 for carrying wafers W to be treated out of a cassette C housing, for example, 25 wafers W and carrying treated wafers W into the cassette C, a treatment station 53 composed of various kinds of treatment units each for performing a predetermined treatment in a single wafer manner on the wafers W in a coating and developing treatment process, and an interface station 54 for passing the wafers W to/from a not-shown exposure apparatus provided adjacent to the treatment station 53.

In the cassette station 52, a plurality of cassettes C can be mounted in a line in an X-direction (a top to bottom direction in FIG. 1) at predetermined positions on a cassette holding table 52a. Adjacent to the cassette holding table 52a, a wafer carrier 52b is provided. The wafer carrier 52b is movable along a carrier path 52c in an arrangement direction of cassettes C (the X-direction), and movable also in a wafer arrangement direction of wafers W (the Z-direction) housed in the cassette C. Thus, the wafer carrier 52b can selectively access the wafers W in each cassette C.

Further, the wafer carrier 52b is configured to be accessible also to an alignment unit G3c and an extension unit G3d included in a third treatment unit group G3 of the treatment station 53 as will be described later.

In the treatment station 53, a main carrier unit 53a is provided at its center portion. Further, four treatment unit groups G1, G2, G3, G4 in each of which various treatment units are multi-tiered and the above-described resist treatment unit 10 are arranged to surround the main carrier unit 53a. The main carrier unit 53a can carry the wafer into/out of the various treatment units in the treatment unit groups G1, G2, G3, G4 and the above-described resist treatment unit 10.

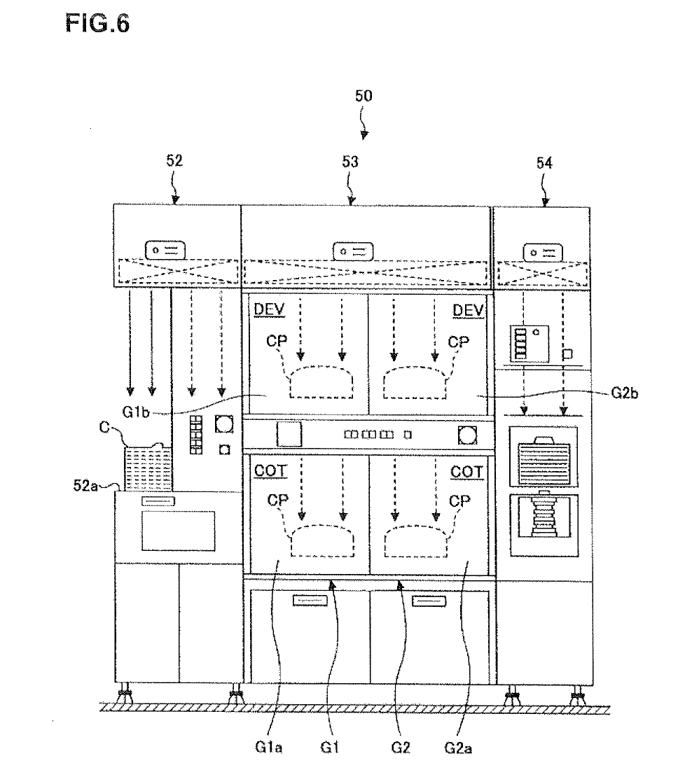

Referring to FIG. 6, in the first treatment unit group G1, a resist coating unit G1a capable of dripping a resist solution onto the wafer W for spin-coating and a developing treatment unit G1b arranged above the resist coating unit G1a for supplying a developing solution to the resist film which has been applied to the wafer W and exposed to light to thereby perform developing treatment, are arranged. In the second treatment unit group G2, a resist coating unit G2a and a developing treatment unit G2b are similarly two-tiered in order from the bottom.

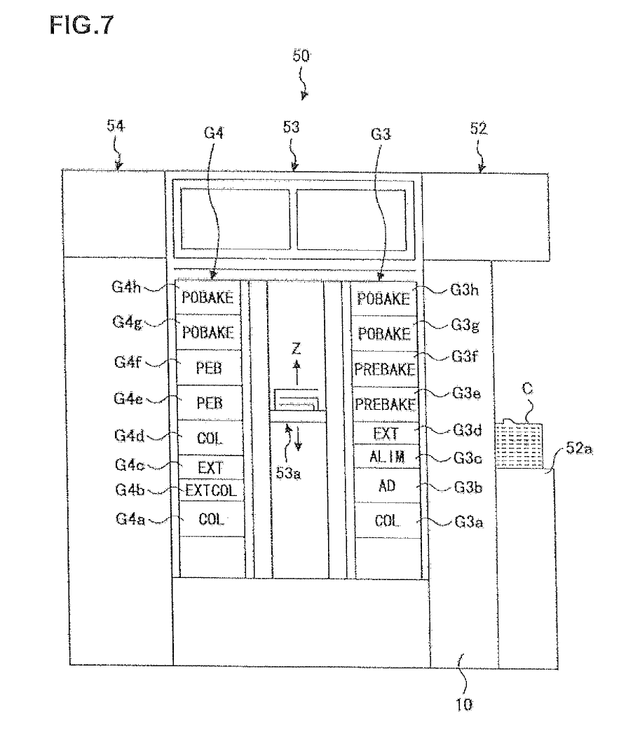

Referring to FIG. 7, in the third treatment unit group G3, a cooling unit G1a for performing cooling treatment on the wafer W, an adhesion unit G3b for enhancing the adhesiveness of the resist to the wafer W, an alignment unit G3c for aligning the wafer W, an extension unit G3d for keeping the wafer W waiting therein, pre-baking units G3e, G3f each for drying the solvent contained in the resist after the resist coating, and post-baking units G3g, G3h each for performing heat processing after developing treatment and the like are, for example, eight-tiered in order from the bottom.

Further, in the fourth treatment unit group G4, for example, a cooling unit G4a, an extension and cooling unit G4b for naturally cooling the wafer W mounted thereon, an extension unit G4c, a cooling unit G4d, post-exposure baking units G4e, G4f each for performing heat processing after exposure processing, and post-baking units G4g, G4h and the like are, for example, eight-tiered in order from the bottom.

Referring again to FIG. 5, a wafer carrier 55 is provided at a middle portion of the interface station 54. The wafer carrier 55 is configured to be movable in the X-direction and the Z-direction and to be rotatable. The wafer carrier 55 can access the extension and cooling unit G4b, the extension unit G4c included in the fourth treatment unit group G4, an edge exposure apparatus 56, and the not-shown exposure apparatus.

Next, a resist coating/exposure/developing process to the wafer W performed in the coating and developing treatment apparatus 50 configured as described above will be described.

First, the wafer carrier 52b (FIG. 5) takes one untreated wafer W out of the cassette C and carries the wafer W into the alignment unit G3c included in the third treatment unit group G3 (FIG. 7). Then, the wafer W aligned in the alignment unit G3c is carried by the main carrier unit 53a to the adhesion unit G3b, the cooling unit G3a, the resist coating unit G1a (G2a) (FIG. 6), and the pre-baking unit G3e (G30 in sequence and subjected to predetermined treatments in the units. After the pre-baking, the wafer W is carried by the wafer carrier 53a to the extension and cooling unit G4b shown in FIG. 7 and cooled to a predetermined temperature. The wafer W is then carried by the wafer carrier 53a to the resist treatment unit 10 and subjected to the above-described resist treatment.

The wafer W is then taken out of the resist treatment unit 10 by the wafer carrier 53a and passed to the wafer carrier 55 (FIG. 5) in the extension unit G4c, and carried to the not-shown exposure apparatus via the edge exposure apparatus 56 in the interface station 54. This exposure apparatus is typically an EUV exposure apparatus, and the wafer W carried to the exposure apparatus is exposed to light in vacuum. The exposed wafer W is carried by the wafer carrier 55 to the extension unit G4c, and then carried by the main carrier unit 53a to the post-exposure baking unit G4e (G4f), the developing treatment unit G1b (G2b) (FIG. 6), the post-baking unit G4g (G4h), and the cooling unit G4d (FIG. 7) in sequence and subjected to predetermined treatments in the units.

As has been described, the coating and developing apparatus according to the embodiment of the present invention includes the resist treatment unit 10 and thus can exhibit the effect of the resist treatment unit 10. Accordingly, the contamination in the exposure apparatus can be reduced, thus making it possible to expose the resist film to light into a predetermined pattern. Further, since the contamination is reduced, the frequency of maintenance of the exposure apparatus can be reduced, thereby making it possible to improve the throughput in the coating and developing apparatus 50.

Though the present invention has been described referring to some embodiments, the present invention is not limited to the above embodiments but can be variously modified based on the attached claims.

For example, the mixture gas of He and Xe is exemplified in the above embodiments, but the mixture gas is not limited to the mixture gas of He and Xe as long as the mixture gas is composed of chemically inert gases. For example, the mixture gas may be composed of He and argon (Ar) gas. In this case, however, since the difference between the molecular weights of He and Ar is smaller than the difference between the molecular weights of He and Xe, the Ar molecule cannot have energy as large as the energy of the Xe molecule. Therefore, the temperature of the uppermost surface of the resist film is relatively low, but the Ar gas is inexpensive as compared to the Xe gas and the use of the Ar gas is advantageous in cost. Accordingly, it is preferable to select a gas depending on the characteristics of the resist in use to thereby exhibit a desired effect. Further, the mixture gas is not limited to the mixture gas composed of two kinds of gases, but a mixture gas composed of three or more kinds of gasses may be used. Use of the mixture gas composed of three or more kinds of gasses makes it possible to more appropriately adjust the effect of reducing the above-described outgas. Note that the chemically inert gas is a gas having a low reactivity with another gas in the mixture gas and the resist film, and is typically a rare gas such as He, neon (Ne), Ar, krypton (Kr), Xe and may be a nitrogen gas. Further, depending on the resist in use, the mixture gas may contain hydrogen gas. In other words, any gas can be used in the resist treatment unit 10 as long as the gas is other than gas which reacts with the resist film to adversely affect the property of the resist or which deposits a hardly removed film on the resist film.

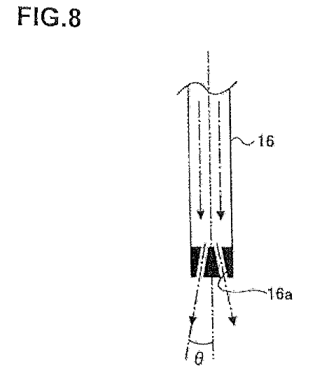

Further, the orifices 16a of the gas nozzle 16 may be formed to tilt at a predetermined angle with respect to the longitudinal direction of the gas nozzle 16. For example, as shown in FIG. 8, when the plurality of orifices 16a are tilted with respect to the center line of the gas nozzle 16 at an outward predetermined angle θ, the application area of the molecular beams can be enlarged and the number of reciprocation times to scan the wafer W which has been described referring to FIG. 2 and FIG. 3 can be reduced. As a result, the throughput can be improved.

Further, the gas nozzle 16 may be, in another embodiment, inserted into the chamber 12 from a side wall of the chamber 12 and bent, for example, in an L-shape in order to face the mounting table 14. This configuration is advantageous in reduction of space.

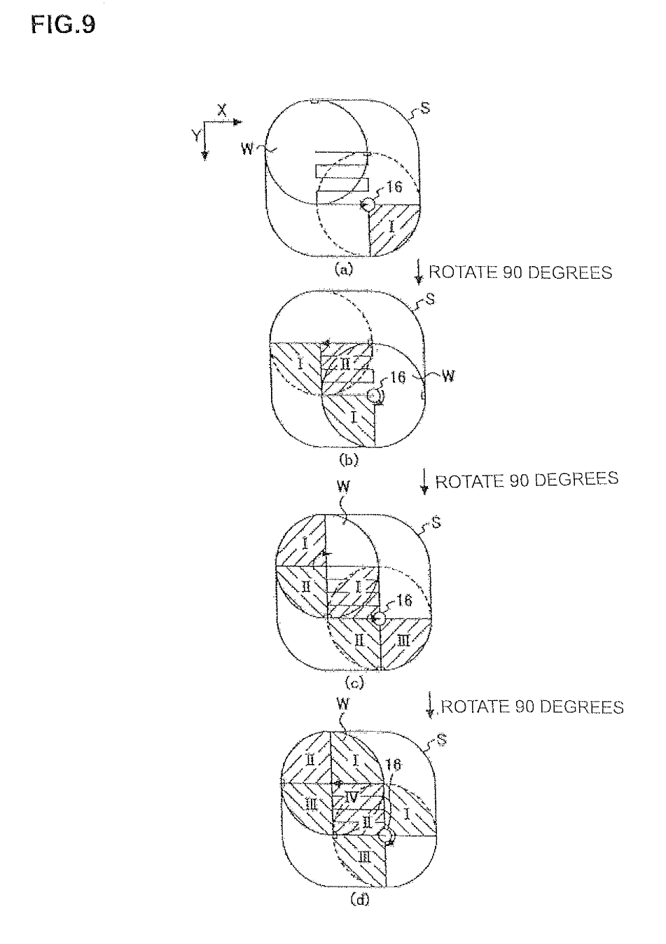

Further, to apply the molecular beams to the wafer W, the mounting table 14 is moved as shown in FIG. 2(a) to FIG. 3(c) in the above-described embodiment, but the mounting table 14 may be moved as shown in FIG. 9 in another embodiment. More specifically, while the gas nozzle 16 is jetting the molecular beams, the wafer W is moved from the initial position by the radius of the wafer W in the positive X-direction, shifted by the width of the application area in the positive Y-direction, and moved by the radius of the wafer W in the negative X-direction. By repeating the above operation, the molecular beams are applied to an area I that is a fourth of the wafer W (FIG. 9(a)). Then, the wafer W is rotated 90 degrees, whereby the applied area I is replaced with an unapplied area II. Then, the wafer W is moved reversely following the path shown in FIG. 9(a) while the gas nozzle 16 is jetting the molecular beams, whereby the molecular beams are applied to the area II that is the next fourth of the wafer W (FIG. 9(b)). Thus, the molecular beams have been applied to a half of the wafer W.

Then, the wafer W is further rotated 90 degrees and similarly moved, and the molecular beams are applied to an area III that is the next fourth of the wafer W (FIG. 9(c)). Further, the wafer W is rotated 90 degrees again, and the molecular beams are applied to an area IV that is a fourth of the wafer W while the wafer W is moved reversely following the path shown in FIG. 9(c) (FIG. 9(d)). Thus, the molecular beams have been applied to the entire surface of the wafer W.

Thus, the space S required for movement of the wafer W only needs to have a length about 1.5 times the diameter of the wafer W both in the X-direction and the Y-direction, so that the space can be further reduced.

Further, though the wafer W in the above embodiment is uniformly scanned so that the molecular beams of the mixture gas are applied to the entire surface of the resist film, the mounting table 14 may be moved step by step so that the application area of the molecular beams corresponds to chips which will be created in the wafer W.

Further, instead of moving the mounting table 14, the gas nozzle 16 may be moved to apply the mixture gas to almost the entire surface of the wafer W, or the orientation of the gas nozzle 16 may be changed to apply the mixture gas to almost the entire surface of the wafer W.

Furthermore, a plurality of gas nozzles 16 may be provided in the resist treatment unit 10 as long as the molecular beams are formed in the chamber 12 of the resist treatment unit 10. This configuration can reduce the time of scanning the wafer W and improve the throughput.

The resist treatment unit 10 is arranged in the treatment station 53 in the above-described coating and developing apparatus 50 (FIG. 5) but, not limited to this, may be arranged at another position. For example, the resist treatment unit 10 can also be arranged, for example, between the extension and cooling unit G4b and the extension unit G4c in the treatment unit group G4. Alternatively, the resist treatment unit 10 may be provided in the interface station 54.

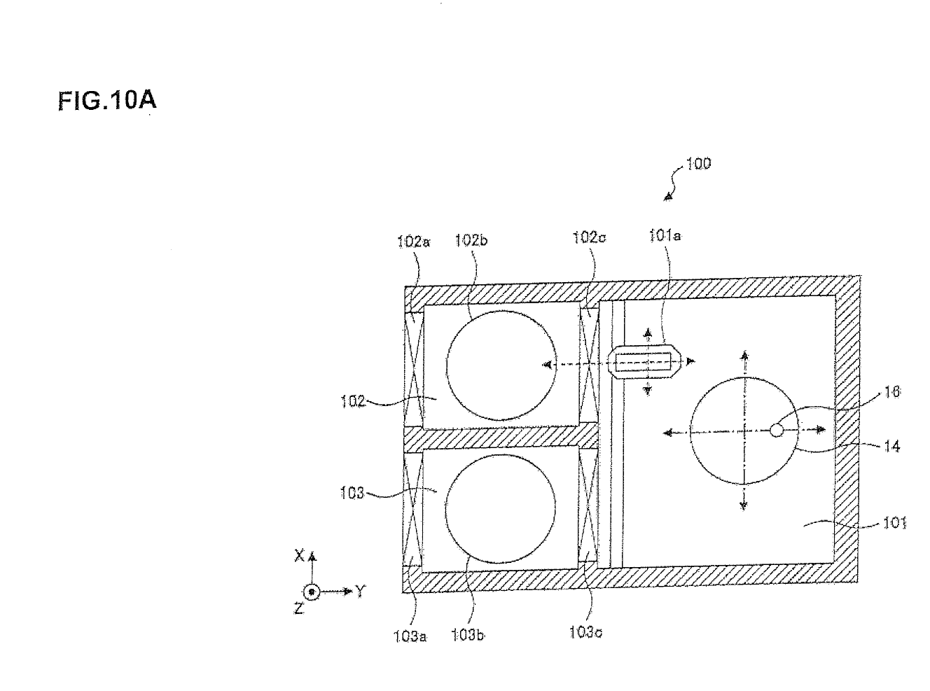

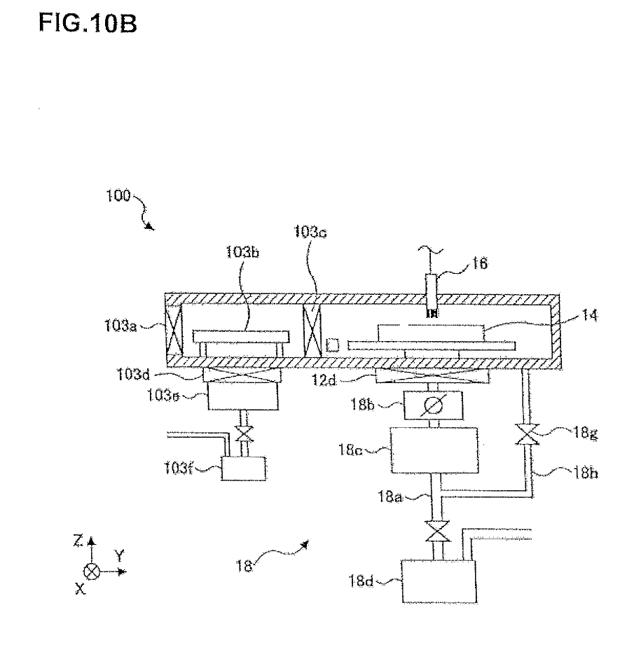

Further, the resist treatment unit 10 can also be configured to be independent from the coating and developing apparatus 50. An example of such a resist treatment unit will be described referring to FIG. 10. As shown in the drawing, a resist treatment unit 100 includes a treatment container 101, a load lock chamber 102 connected to the treatment container 101 via a gate valve 102c, and a load lock chamber 103 connected to the treatment container 101 via a gate valve 103c.

The treatment container 101 includes a mounting table 14 on which a wafer having a resist film formed thereon is mounted, a gas nozzle 16 for applying molecular beams to the wafer mounted on the mounting table 14, and a carrier 101a for carrying the wafer into/from the mounting table 14 (FIG. 10A). The mounting table 14 is movable in an X-direction and a Y-direction by a predetermined stage as shown by arrows of one-dotted chain lines in FIG. 10A. A gas supply system (not shown) that is similar to the gas supply system 17 shown in FIG. 1 is connected to the gas nozzle 16 and thereby can apply molecular beams of a mixture gas composed of, for example, He gas and Xe gas to the wafer mounted on the mounting table 14. Further, the carrier 101a can move in the X-direction and the Y-direction as shown by arrows of broken lines in the drawing. Thus, the carrier 101a can access the inside of the load lock chamber 102 when the gate valve 102c is opened, access the inside of the load lock chamber 103 when the gate valve 103c is opened, and access the mounting table 14.

Further, to the treatment container 101, a vacuum system 18 is connected via a valve 12d as in the resist treatment unit 10 (FIG. 10B). The vacuum system 18 can be used to maintain a high vacuum inside the treatment container 101, whereby the mixture gas from the gas nozzle 16 can be made into molecular beams.

The load lock chamber 103 has a holding table 103b for temporarily holding the wafer thereon, and another gate valve 103a opposite the gate valve 103c across the holding table 103b. Further, at a lower portion of the load lock chamber 103, a high vacuum pump 103e such as a turbo-molecular pump connected to the load lock chamber 103 via a valve 103d, and a dry pump 103f serving as an auxiliary pump of the high vacuum pump 103e and as a roughing pump for exhausting the load lock chamber 103 via the high vacuum pump 103e, are provided.

Note that the load lock chamber 102 is configured similarly to the load lock chamber 103.

In the resist treatment unit 100 having such a configuration, a vacuum can be maintained in the treatment container 12 and the resist film on the wafer is treated as follows. First, the gate valve 102a of the load lock chamber 102 at air pressure is opened, and a wafer is then mounted on the holding table 102b of the load lock chamber 102 by a predetermined carrier arm. After the gate valve 102a is closed, the load lock chamber 102 is evacuated to a predetermined degree of vacuum. Then, the gate valve 102c is opened, and the wafer is carried by the carrier 101a from the load lock chamber 102 into the treatment container 101 and mounted on the mounting table 14. Subsequently, the above-described resist treatment is performed in the treatment container 101. The load lock chamber 103 is evacuated in this period, and after the resist treatment is finished, the gate valve 103c is opened and the wafer is mounted on the holding table 103b of the load lock chamber 103 by the carrier 101a, and the gate valve 103c is closed. Then, the inside of the load lock chamber 103 is brought again to the air pressure, the gate valve 103a is opened, and the wafer W is carried out by the predetermined carrier arm.

The provision of the load lock chambers as described above can maintain a high vacuum inside the treatment container 101 and reduce the time required for evacuating the treatment container 101. Therefore, the throughput can be improved.

Further, the resist treatment unit 100 can be connected to the coating and developing apparatus 50 or the exposure apparatus via a predetermined interface section, whereby the wafer can be passed between the resist treatment unit 100 and the coating and developing apparatus 50 or the exposure apparatus. Note that the above-described various modifications are applicable also to the resist treatment unit 100. Further, it goes without saying that the load lock chambers are also applicable to the case where the resist treatment unit 10 is provided in the coating and developing apparatus 50.

Further, the wafer W is not limited to the semiconductor wafer but may be a glass substrate for a flat panel display (FPD).

This international application is based upon and claims the benefit of priority from the prior Japanese Patent Application No. 2008-177376, filed on Jul. 7, 2008; the entire contents of which are incorporated herein by reference.

What is claimed:

1. A resist treatment unit for performing treatment on a resist film which has been formed on a substrate, said unit comprising:
a treatment container capable of maintaining a vacuum therein;
a mounting table provided in said treatment container for mounting the substrate on which the resist film has been formed thereon;
a gas supply part for jetting a mixture gas containing a first gas and a second gas which are chemically inert toward said mounting table at a predetermined flow rate; and
an exhaust part capable of exhausting said treatment container to a degree of vacuum at which the mixture gas jetted from said gas supply part at the predetermined flow rate is able to be a molecular beam in said treatment container.

2. The resist treatment unit as set forth in claim 1, wherein the first and second gasses are rare gasses.

3. The resist treatment unit as set forth in claim 2, wherein the first gas is helium gas and the second gas is xenon gas.

4. The resist treatment unit as set forth in claim 1, wherein the resist film is a chemically amplified resist film.

5. The resist treatment unit as set forth in claim 1, further comprising:
a load lock chamber having two valves allowing the substrate to pass through and connected to said treatment container via one of the two valves.

6. A resist coating and developing apparatus, comprising:
a resist coating unit for applying a resist film onto a substrate;
a resist treatment unit for performing treatment on the resist film, said resist treatment unit being the resist treatment unit as set forth in claim 1; and
a developing unit for developing the resist film for which the treatment has been performed and exposure processing has been performed.

7. The resist coating and developing apparatus as set forth in claim 6, further comprising:
a pre-baking unit for heating the resist film applied on the substrate.

8. A resist treatment method, comprising the steps of:
mounting a substrate on which a resist film has been applied on a mounting table provided in a treatment container;
exhausting the treatment container to be able to form a molecular beam in the treatment container; and
jetting a mixture gas containing a first gas and a second gas which are chemically inert into the treatment container to form a molecular beam, and applying the molecular beam to the substrate mounted on the mounting table.

9. The resist treatment method as set forth in claim 8, wherein the first and second gasses are rare gasses.

10. The resist treatment method as set forth in claim 9, wherein the first gas is helium gas and the second gas is xenon gas.
